(19) United States
(12) Patent Application Publication
(10) Pub. No.: US 2007/0084562 A1
(43) Pub. Date: Apr. 19, 2007

(54) Plasma processing chamber

(75) Inventor: Hiroshi Tsujimoto, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Minato-ku (JP)

(21) Appl. No.: 11/518,228

(22) Filed: Sep. 11, 2006

Related U.S. Application Data
(60) Provisional application No. 60/731,284, filed on Oct. 31, 2005.

(30) Foreign Application Priority Data
Sep. 30, 2005 (JP) 2005-288356

(51) Int. Cl. H01L 21/306

(52) U.S. Cl. 156/345.24

(57) ABSTRACT

A plasma processing chamber includes a vessel for accommodating therein a substrate; a gas supply unit for supplying a processing gas into the vessel; an electrode for applying a high frequency power into the vessel; a gas exhaust unit, connected to the vessel, for discharging gas from the vessel; and a particle detector for detecting particles floating in the vessel. The particle detector is positioned on a passage functioning as a free-fall path of the particles and also as a moving path of particles carried by the gas discharged from the vessel through the gas exhaust unit. Further, the gas exhaust unit of the plasma processing chamber has a gas exhaust port opened in the vessel toward the free-fall path of the particles.

### CROSS-REFERENCE TO RELATED APPLICATIONS

This document claims priority to Japanese Patent Application No. 2005-288356, filed on Sep. 30, 2005 and U.S. Provisional Application No. 60/731,284, filed on Oct. 31, 2005, the entire content of which are hereby incorporated by reference.

### FIELD OF THE INVENTION

The present invention relates to a plasma processing chamber having a vessel; and, more particularly, to a plasma processing chamber having a particle detector for detecting a state of particles generated in the vessel thereof.

### BACKGROUND OF THE INVENTION

There is known a plasma processing apparatus including a chamber (vessel) serving as a vacuum processing chamber for accommodating therein a wafer as a substrate, a mounting table (susceptor) for mounting thereon the wafer accommodated in the chamber, a shower head for supplying a processing gas into the chamber, an electrode for applying a high frequency power into the chamber, and so on.

In such plasma processing apparatus, ions or the like are generated by converting the processing gas supplied to the chamber into plasma with a high frequency power. A plasma processing is then performed on a wafer surface with the generated ions or the like. At this time, substances remaining on the wafer surface react with the ions or the like, thereby generating reaction products. The reaction products are then adhered to an inner wall surface of the chamber, which in turn, get peeled off during the plasma processing, resulting in particles. These particles float inside the chamber and are adhered to the wafer surface or the like.

Here, if the particles are adhered to semiconductor devices on the wafer, a wiring of the semiconductor devices can be subject to short-circuit, which could deteriorate a production yield of the semiconductor devices. Thus, there has been a need to detect a state of particles generated in the chamber, specifically, to measure the particle sizes and the number of particles.

To accomplish the above object, there has been developed a plasma processing apparatus for detecting a state of particles at a location close to a chamber in which the particles are generated, wherein the plasma processing apparatus is equipped with a particle detector for detecting particles with laser beam at an exhaust passage employed for discharging gas from the chamber or at an exhaust forechamber disposed at a location between the chamber and the exhaust passage (see, e.g., Patent Reference I).

It has been recently discovered that a movement of particles changes according to pressure inside the chamber. To be specific, the inventor has found that when the pressure inside the chamber is high, the particles move along an exhaust stream of the gas in the chamber, whereas when the pressure inside the chamber is low, the particles move (fall) by the gravity without moving along the exhaust stream of the gas in the chamber. Therefore, when the pressure in the aforementioned plasma processing chamber is low, the particles are held up from flowing into the exhaust passage or the exhaust forechamber, thereby disallowing an accurate detection of the state of particles.

Because of the above drawback, there has been developed a method capable of accurately detecting a state of particles by causing the particles to flow into the exhaust passage along an air flow therethrough generated by means of increasing a gas pressure in the chamber above a specific level. This increase in gas pressure is achieved through an introduction of a processing gas into the chamber after a plasma processing or after a cleaning process (e.g., dry cleaning) of the inside of the chamber (see, e.g., Patent Reference II).

However, there has recently been a demanding need to detect a state of particles generated in the chamber not only after the plasma processing and the cleaning of the inside of the chamber, but also during the plasma processing.
[Patent Reference I] Japanese Patent Laid-open Application No. H9-203704
[Patent Reference II] Japanese Patent Laid-open Application No. H6-94597

However, since the inside of the chamber is depressurized during the plasma processing, especially during an etching processing, the state of the particles in the chamber cannot be detected with the aforementioned method (i.e. by increasing the gas pressure in the chamber above a specific level). In other words, a detection of the particle state in the chamber only can be enabled depending on the pressure in the chamber.

### SUMMARY OF THE INVENTION

It is, therefore, an object of the present invention to provide a plasma processing chamber capable of detecting a state of particles in a vessel regardless of a pressure in the vessel.

In accordance with a first aspect of the present invention, there is provided a plasma processing chamber including:

a vessel for accommodating therein a substrate;

a gas supply unit for supplying a processing gas into the vessel;

an electrode for applying a high frequency power into the vessel;

a gas exhaust unit, connected to the vessel, for discharging gas from the vessel; and

a particle detector for detecting particles floating in the vessel,

wherein the particle detector is positioned on a passage functioning as a free-fall path of the particles and also as a moving path of the particles carried by the gas discharged from the vessel through the gas exhaust unit.

In accordance with the plasma processing chamber of the first aspect, the particle detector is positioned on a free-fall path of the particles and also on a moving path of the particles carried by the gas discharged from the vessel through the gas exhaust unit. When the pressure within the vessel is high, the particles move along the gas exhaust stream generated by the main exhaust line, whereas when the pressure within the vessel is low, the particles freely fall by the gravity. Consequently, the particles move along the side exhaust passage regardless of the pressure in the chamber. As a result, the particle counter disposed at the side exhaust passage can detect the state of the particles in the vessel regardless of the pressure therein.

Further, in the plasma processing chamber of the first aspect, the gas exhaust unit may have a gas exhaust port opened in the vessel toward the free-fall path of the particles.

In case the gas exhaust unit has the gas exhaust port opened in the vessel toward the free fall path of the particles, the gas exhaust stream generated by discharging the gas in the vessel can accurately correspond to the free fall path of the particles. As a result, it is possible to accurately detect the state of the particles therein.

In accordance with a second aspect of the present invention, a plasma processing chamber may include:

a vessel for accommodating therein a substrate;

a gas supply unit for supplying a processing gas into the vessel;

an electrode for applying a high frequency power into the vessel;

a gas exhaust unit, connected to the vessel, for discharging gas in the vessel; and

a particle detector for detecting particles floating in the vessel,

wherein the gas exhaust unit includes a first exhaust passage for depressurizing an inside of the vessel from the atmospheric pressure to a low vacuum level; and a second exhaust passage for depressurizing the inside of the vessel by cooperating with the first exhaust passage from the atmospheric pressure to a high vacuum level having a pressure lower than the low vacuum level, and

wherein the first and the second exhaust passage have a first and a second exhaust port opened in the vessel toward a free-fall path of the particles, respectively.

The plasma processing chamber of the second aspect includes the particle detector for detecting particles floating in the vessel; and the first exhaust passage for depressurizing the inside of the vessel from an atmospheric pressure to the low vacuum level and the second exhaust passage for depressurizing the inside of the vessel together with the first exhaust passage from the atmospheric pressure to a high vacuum level having a pressure lower than the low vacuum level have the first and the second exhaust passages, respectively. Also, the first and second exhaust port are opened in the vessel toward a free-fall path of the particles and the path in which the particles are moved toward the first and second exhaust ports coincide with the free-fall path of the particles. In addition, when the pressure within the vessel is low, the particles fall freely by the gravity, whereas when the pressure within the vessel is high, the particles move along the gas exhaust stream generated by the main exhaust line. Consequently, the particles move along the side exhaust passage regardless of the pressure in the vessel. As a result, the particle counter can detect the state of the particles in the vessel regardless of the pressure therein.

Further, in the plasma processing chamber of the second aspect, while further including a partition plate for partitioning the vessel into a reaction chamber where the substrate is disposed and the exhaust chamber connected to the gas exhaust unit, the particle detector may be provided in the exhaust chamber and has a laser generating part for emitting laser beam for testing along a direction in which the first and the second exhaust port are disposed.

In accordance with the plasma processing chamber of the second aspect, in case the particle detector is provided in the exhaust chamber with the partition plate, the laser generating part generates a laser beam for testing along a direction in which the first and the second exhaust port are disposed. A stray light in a reaction chamber is blocked by the partition plate and fails to reach the exhaust chamber. Also, while the second exhaust passage is depressurized from the atmospheric pressure to the high vacuum level, the particles are flown into the passage thereof. As a result, the particle counter can detect the state of the particles in the vessel regardless of the pressure therein.

In accordance with a third aspect of the present invention, a plasma processing chamber may include:

a vessel for accommodating therein a substrate;

a gas supply unit for supplying a processing gas into the vessel;

an electrode for applying a high frequency power into the vessel;

a gas exhaust unit, connected to the vessel, for discharging gas in the vessel; and

a particle detector for detecting particles floating in the vessel,

wherein the gas exhaust unit includes a first exhaust passage for depressurizing an inside of the vessel from the atmospheric pressure to a low vacuum level; a second exhaust passage for depressurizing the inside of the vessel by cooperating with the first exhaust passage from the atmospheric pressure to a high vacuum level having a lower pressure than the low vacuum level; and a third exhaust passage for communicating the first and the second exhaust passage with the inside of the vessel, and wherein the third exhaust passage has an exhaust port opened in the vessel toward a free fall path of the particles.

The plasma processing chamber of the third aspect includes the particle detector for detecting particles floating in the vessel; and the third exhaust passage, which is for communicating the first exhaust passage for depressurizing the inside of the vessel from an atmospheric pressure to the low vacuum level and the second exhaust passage for depressurizing the inside of the vessel together with the first exhaust passage from the atmospheric pressure to the high vacuum level having a lower pressure than the low vacuum level, has the exhaust port opened in the vessel toward a free fall path of the particles. Also, the path in which the particles are moved toward the first and second exhaust port corresponds with the free-fall path of the particles. In addition, when the pressure within the vessel is low, the particles freely fall due to the gravity, whereas when the pressure within the vessel is high, the particles move along the gas exhaust stream generated by the main exhaust line. Consequently, the particles move along the side exhaust passage regardless of the pressure in the vessel. As a result, the particle counter passage can detect the state of the particles in the vessel regardless of the pressure therein.

Further, in the plasma processing chamber of the third aspect, the particle detector may be provided in the third exhaust passage and has a laser generating part for emitting a laser beam for testing toward a flow path of the third exhaust passage.

In accordance with the plasma processing chamber of the third aspect, the particle detector is disposed at the third exhaust passage, and the laser generating part of the particle detector emits the laser beam toward the third exhaust passage. Also, during the third exhaust passage is depressurized from the atmospheric pressure to the high vacuum level, the particles are flown into the passage thereof. As a result, the particle counter can detect the state of the particles in the vessel regardless of the pressure therein.

Further, in the plasma processing chamber of the third aspect, further comprising a partition plate for partitioning the vessel into a reaction chamber where the substrate is disposed and an exhaust chamber connected to the gas exhaust unit, the particle detector may be provided in the exhaust chamber and has a laser generating part for emitting the laser beam for testing toward the free-fall path of the particles.

In accordance with the plasma processing chamber of the third aspect, in case the particle detector is provided in the exhaust chamber with the partition plate, the laser generating part emits the laser beam for testing along the free-fall path of the particles. A stray light in a reaction chamber is blocked by the partition plate and fails to reach the exhaust chamber. In addition, the particles move along the free-fall path such as the path of which the particles move toward the exhaust passage regardless of the pressure therein. As a result, the particle counter can detect the state of the particles in the vessel regardless of the pressure therein.

### BRIEF DESCRIPTION OF THE DRAWINGS

The above and other objects and features of the present invention will become apparent from the following description of preferred embodiments, given in conjunction with the accompanying drawings, in which:

FIG. 1 is a schematic cross sectional view of a plasma processing chamber in accordance with a first preferred embodiment of the present invention;

FIGS. 2A to 2D illustrate movements of substituted particles at various pressures present in the reaction chamber of FIG. 1, wherein FIGS. 2A to 2D describe movements of the substituted particles at the pressures of 119 Pa, 66.7 Pa, 26.7 Pa and 6.67 Pa, respectively;

FIG. 3 shows a schematic top view of a particle counter of FIG. 1;

FIG. 4A provides a schematic cross sectional view of a plasma processing chamber in accordance with a second preferred embodiment of the present invention, and FIG. 4B presents a schematic cross sectional view taken along the line 4B-4B of FIG. 4A;

FIGS. 5A represents a schematic cross sectional view of a plasma processing chamber in accordance with a third preferred embodiment of the present invention, and FIG. 5B offers a schematic cross sectional view taken along the line 5B-5B of FIG. 5A;

FIG. 6 illustrates a schematic cross sectional view of a modified example of the plasma processing chamber in accordance with the second preferred embodiment of the present invention;

FIG. 7 provides a schematic cross sectional view of a first modified example of the plasma processing chamber in accordance with the third preferred embodiment of the present invention; and

FIGS. 8A is a schematic cross sectional view of a second modified example of the plasma processing chamber in accordance with the third preferred embodiment of the present invention, and FIG. 8B shows a schematic cross sectional view taken along the line 8B-8B of FIG. 8A.

### DETAILED DESCRIPTION OF THE PREFERRED EMBODIMENTS

Preferred embodiments of the present invention will be described in detail with reference to the accompanying drawings.

First, a plasma processing chamber in accordance with a first preferred embodiment of the present invention will be described.

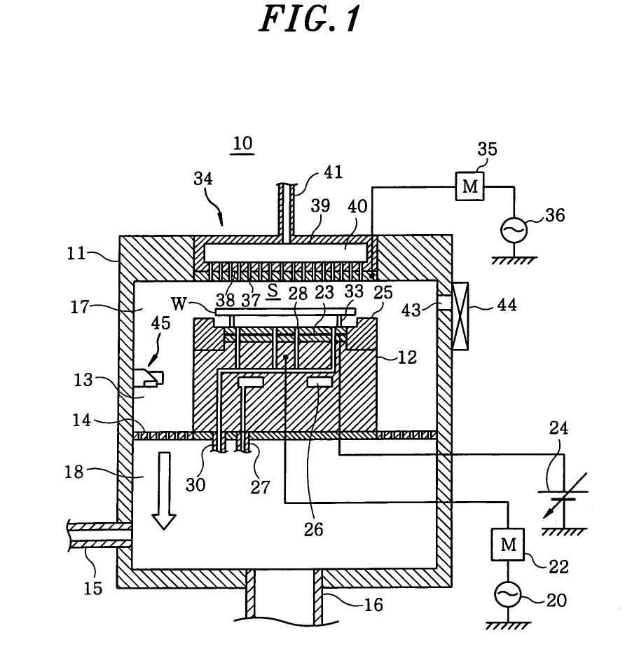

FIG. 1 is a schematic cross sectional view of the plasma processing chamber 10 in accordance with the first preferred embodiment of the present invention. The plasma processing chamber 10 is configured to perform a RIE (reactive ion etching) process on a semiconductor wafer serving as a substrate.

The plasma processing chamber 10 of FIG. 1 includes a chamber (vessel) 11 for accommodating therein a semiconductor wafer W (hereinafter, simply referred to as “wafer”) having a diameter of 300 mm, for example. Installed in the chamber 11 is a cylindrical susceptor 12 serving as a mounting table for mounting thereon the wafer W.

In the plasma processing chamber 10, a side exhaust passage 13 for discharging gas existing above the susceptor 12 to the outside of the chamber 11 is formed between an inner wall of the chamber 11 and a side surface of the susceptor 12. Further, a baffle plate 14 is provided at the bottom of the side exhaust passage 13.

The baffle plate 14 is a plate-shaped member having a plurality of holes and serves as a partition plate for partitioning the chamber 11 into an upper and a lower part. The upper part of the chamber 11 partitioned by the baffle plate 14 is provided with the susceptor 12, for mounting thereon the wafer W, and so forth; and a plasma to be described later is generated therein. Hereinafter, the upper part of the chamber 11 is referred to as a “reaction chamber.” Moreover, a rough exhaust line 15 and a main exhaust line 16 (first and second exhaust passages, respectively) for discharging the gas in the chamber 11 are opened in the lower part of the chamber 11 (hereinafter, referred to as “exhaust chamber (manifold)”) . The rough exhaust line 15 is connected with a DP (dry pump) (not shown), whereas the main exhaust line 16 is connected with a TMP (turbo molecular pump) (not shown). Further, the baffle plate 14 prevents leaking of ions or radicals generated in a processing space S to be described later of a reaction chamber 17 into the manifold 18 by confining or reflecting the ions or the radicals.

A gas exhaust unit is formed of the rough exhaust line 15, the main exhaust line 16, the DP, the TMP and the like. The rough exhaust line 15 and the main exhaust line 16 discharge the gas in the reaction chamber 17 to the outside of the chamber 11 via the manifold 18. To be specific, the rough exhaust line 15 depressurizes an inside of the chamber 11 from the atmospheric pressure to a low vacuum level. The main exhaust line 16 also depressurizes the inside of the chamber 11 together with the rough exhaust line 15 from the atmospheric pressure to a high vacuum level (e.g., equal to below 133 Pa (1 Torr)) lower than the low vacuum level.

A lower high frequency power supply 20 is connected with the susceptor 12 via a matcher (M) 22, thereby supplying a specific high frequency power to the susceptor 12. In this way, the susceptor 12 serves as a lower electrode. Further, the matcher 22 maximizes the efficiency of applying the high frequency power to the susceptor 12 by reducing a reflection of the high frequency power from the susceptor 12.

A circular-shaped ESC electrode plate 23 made of a conductive film is provided at an inner upper portion of the susceptor 12. Moreover, a DC power supply 24 is electrically connected with the ESC electrode plate 23. The wafer W is adsortively held on a top surface of the susceptor 12 by the Coulomb force or the Johnson-Rahbek force generated by a DC voltage applied from the DC power supply 24 to the ESC electrode plate 23. Furthermore, a ring-shaped focus ring 25 is provided at an upper portion of the susceptor 12 to surround a periphery of the wafer W adsorptively held on the top surface of the susceptor 12. The focus ring 25 is exposed to the processing space S (to be described later) and collects plasma toward a surface of the wafer W in the processing space S, thereby improving an efficiency of the RIE process.

Installed in the susceptor 22 are, for example, a ring-shaped coolant chamber 26 extending in a circumferential direction. A coolant, e.g., a cooling water or Galden, of a specific temperature is circulatively supplied from a chiller unit (not shown) into the coolant chamber 26 via a coolant line 27. A processing temperature of the wafer W adsorptively held on the top surface of the susceptor 12 is therefore controlled based on the temperature of the coolant.

A plurality of thermally conductive gas supply openings 28 are opened at a portion of the top surface of the susceptor 12 where the wafer W is adsorptively held on (hereinafter, referred to as an “adsorption surface”). Such thermally conductive gas supply openings 28 are connected with a thermally conductive gas supply unit (not shown) via a thermally conductive gas supply line 30. The thermally conductive gas supply unit supplies a He gas as a thermally conductive gas to a gap between the adsorption surface and a backside of the wafer W via the thermally conductive gas supply openings 28. The He gas supplied to the gap therebetween transfers heat from the wafer W to the susceptor 12.

Further, provided on the adsorption surface of the susceptor 12 are a plurality of pusher pins 33 serving as lift pins capable of freely protruding from the top surface of the susceptor 12 whenever necessary. The pusher pins 33 are connected with a motor (not shown) through a ball screw (not shown) and thus can be freely protruded from the adsorption surface by converting rotation force of the motor into a linear movement using the ball screw. When the wafer W is held adsorptively on the adsorption surface to perform the RIE process, the pusher pins 33 are accommodated within the susceptor 12. However, in case the wafer W that has been subjected to the RIE process is to be unloaded from the chamber 11, the pusher pins are protruded from the top surface of the susceptor 12 and then are used to raise the wafer W upwards from the susceptor 12.

A gas inlet shower head 34 (processing gas supplying unit) is disposed at a ceiling portion of the chamber 11 (reaction chamber 17) such that it can face the susceptor 12. Moreover, an upper high frequency power supply 36 is connected with the gas inlet shower head 34 via a matcher (M) 35 and thus supplies a specific high frequency power to the gas inlet shower head 34. Therefore, the gas inlet shower head 34 functions as an upper electrode. The matcher 35 also functions in the same manner in the aforementioned matcher 22.

The gas inlet shower head 34 includes a ceiling electrode plate 38 having a plurality of gas openings 37 and an electrode support 39 for attachably and detachably supporting the ceiling electrode plate 38. Further, a buffer chamber 40 is provided within the electrode support 39 and also connected with a processing gas inlet line 41. The gas inlet shower head 34 supplies the processing gas introduced into the buffer chamber 40 through the processing gas inlet line 41 into the chamber 11 (reaction chamber 17) via the gas openings 37.

Moreover, a loading/unloading port 43 of the wafer W is provided on a sidewall of the chamber 11 at a height of the wafer W that has been upwardly lifted from the susceptor 12 by the pusher pins 33. Further, the loading/unloading port 43 is provided with a gate valve 44 for opening and closing the loading/unloading port 43.

In the chamber 11 of the plasma processing chamber 10, the RIE process is performed on the wafer W by using ions or radicals generated by converting the processing gas supplied from the gas inlet shower head 34 into a high-density plasma in the processing space S with the high frequency powers applied to the processing space S between the susceptor 12 and the gas inlet shower head 34 as described above.

Furthermore, a CPU of a control unit (not shown) included in the plasma processing chamber 10 operates the aforementioned components of the plasma processing chamber 10 under a control of a program dedicated to the RIE process.

The plasma processing chamber 10 is connected with a LM (loader module) (not shown) for transferring the wafer W via a LLM (load lock module) (not shown) for, e.g., supplying the wafer W to the plasma processing chamber 10. The plasma processing chamber 10, the LLM and the LM constitute the plasma processing apparatus.

In the plasma processing chamber 10, the ions or the like react with substances existing on the wafer surface, thereby generating reaction products while the RIE process is performed on the wafer W. The reaction products get adhered to an inner wall surface of the reaction chamber 17 and then get peeled off during a next cycle of the RIE process or the like, generating particles. Since the generated particles get adhered to the surface of the wafer W or the like while being floated in the reaction chamber 17, the gas exhaust unit is configured to discharge the particles to the outside of the chamber 10 via the side exhaust passage 13 and the manifold 18.

The plasma processing chamber 10 has the configuration same as that of a conventional plasma processing chamber.

Prior to the present invention, the present inventor observed movements of substitute particles at different pressures in order to check a relationship between pressure in the chamber 11 and a movement of particles in both the reaction chamber 17 and the manifold 18. To be specific, PTFE (tetra-fluoroethylene) resin particles having a particle diameter of 0.5 μm as substitute particles were placed on the susceptor 12. Then, by supplying a high frequency power to the susceptor 12 or by introducing He gas into the reaction chamber 17 through the thermally conductive gas supply openings 28, the PTFE particles were dispersed in the chamber 11. Next, by emitting laser beam through the manifold 18 while the inside of the chamber 11 was maintained at a specific pressure condition by the gas exhaust unit, a moving path of the substitute particles passing through the laser beam thereof was observed.

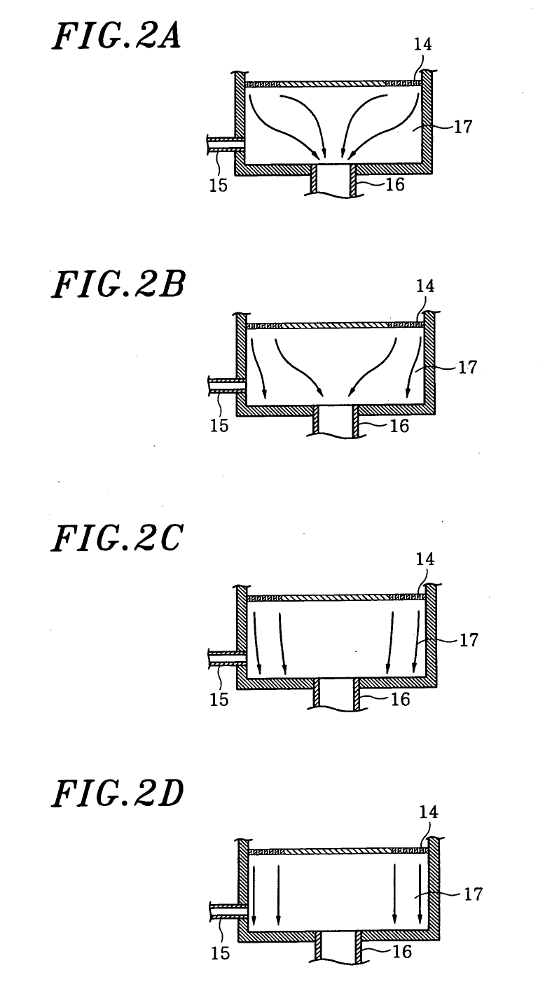

Since the pressure in the chamber 11 is normally maintained at several Pa to about 133 Pa (1 Torr) during the RIE process, the pressure in the chamber 11 were set as 119 Pa (900 mTorr), 66.7 Pa (500 mTorr), 26.7 Pa (200 mTorr) and 6.67 Pa (50 mTorr). The movements of the substitute particles at the respective pressures are indicated by arrows shown in FIGS. 2A to 2D.

FIGS. 2A to 2D illustrate the movements of the substitute particles at the respective pressures in the reaction chamber of FIG. 1. Specifically, FIGS. 2A to 2D describe the movements of the substitute particles at the pressures of 119 Pa, 66.7 Pa, 26.7 Pa and 6.67 Pa, respectively.

In case the pressure in the chamber 11 is comparatively high (e.g., 119 Pa or 66.7 Pa), it was observed that the substitute particles introduced into the manifold 18 through the baffle plate 15 were pulled into the main exhaust line 16. However, in case the pressure in the chamber 11 was comparatively low (e.g., 26.7 Pa or 6.67 Pa), it was observed that the substitute particles introduced into the manifold 18 through the baffle plate 15 fell freely without being pulled into the main exhaust line 16. Further, these substitute particles were elastically bounced up and down while colliding with a bottom surface of the manifold 18 and then stopped on the bottom surface thereof shortly thereafter.

In the meantime, as a result of observing the moving paths of the substitute particles in the side exhaust passage 13 while transmitting the laser beam therethrough, it was found that the moving path is the same regardless of the pressure in the chamber 11. This has been believed to be the case because the moving path of the substitute particles transferred by the gas exhaust stream is identical to a free-fall path of the substitute particles in the side exhaust passage 13.

Referring back to FIG. 1, in the plasma processing chamber 10 in accordance with this embodiment, a particle counter (particle detector) 45 for detecting particles is provided at the side exhaust passage 13. This is because the moving path of particles changes according to the pressure in the chamber 11 in the manifold 18.

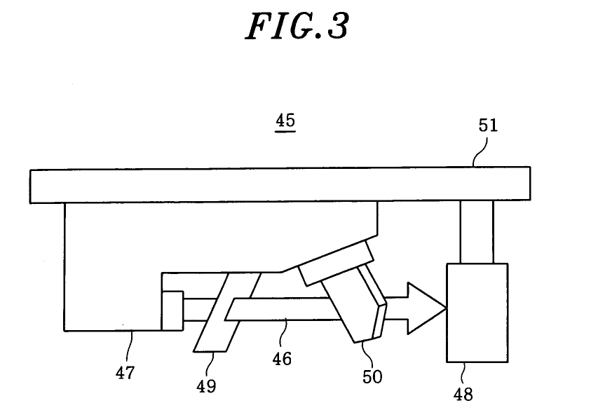

FIG. 3 provides a schematic top view of the particle counter in FIG. 1.

Referring to FIG. 3, the particle counter 45 includes a laser generating part 47 for generating laser beam 46; a laser stopper 48 for blocking the laser beam 46; a laser beam shaper 49, disposed between the laser generating part 47 and the laser stopper 48, for shaping the laser beam 46 into a strip shape with the use of a slit; a detector 50, disposed between the laser beam shaper 49 and the laser stopper 48, having a sensor (not shown) for detecting reflected lights generated by particles passing through the strip-shaped laser beam 46; a base portion to which the laser generating part 47, the laser stopper 48, the laser beam shaper 49 and the detector 50 are attached; and a control unit (not shown) for controlling the laser generating part 47 and the detector 50.

In the particle counter 45, the laser generating part 47, the laser beam shaper 49 and the detector 50 are protruded in the side exhaust passage 13, thereby detecting sizes and the number of particles passing through the strip-shaped laser beam 46 between the laser beam shaper 49 and the laser stopper 48 among the particles flowing in the side exhaust passage 13. To be specific, the detector 50 receives the reflected lights generated by the particles passing through the laser beam 46 and further converts the reflected lights into voltage. Accordingly, the control unit detects the sizes and the number of particles based on the intensities detected and the number of peaks in the converted voltage.

Referring back to FIG. 1, the particle counter 45 is installed in the side exhaust passage 13. At the side exhaust passage 13, the moving path of the particles carried by the gas exhaust stream is identical to the free-fall path of the particles. Therefore, the particle counter 45 is disposed on the free-fall path of the particles and also on the moving path of the particles carried by the gas discharged from the chamber 11 through the rough exhaust line 15 and/or the main exhaust line 16.

In accordance with the aforementioned plasma processing chamber 10, the particle counter 45 is provided at the side exhaust passage 13 functioning as the free-fall path of the particles and the moving path of the particles carried by the gas discharged from the chamber 11 through the rough exhaust line 15 and/or the main exhaust line 16. When the pressure is comparatively high, the particles move along the gas exhaust stream generated by the rough exhaust line 15 and/or the main exhaust line 16. On the contrary, when the pressure is comparatively low, the particles fall freely due to gravity. Consequently, the particles move along the side exhaust passage 13 regardless of the pressure in the chamber 11. As a result, regardless of the pressure present in the chamber 11, the particle counter 45 disposed at the side exhaust passage 13 can detect the sizes and the number of particles in the chamber 11.

Moreover, the aforementioned plasma processing chamber 10 has a configuration that is same as that of the conventional plasma processing chamber except that there is added the particle counter 45 disposed at the side exhaust passage 13. Therefore, the plasma processing chamber 10 can be achieved by modifying the conventional plasma processing chamber at a minimum level, thereby restricting an increase in the fabrication cost of the plasma processing chamber 10.

In the plasma processing chamber 10, the gas exhaust port of the rough exhaust line 15 and the main exhaust line 16 can be established anywhere in the manifold 18. However, it is preferable that the gas exhaust ports of the rough exhaust line 15 and the main exhaust line 16 be opened toward an extended path (indicated by a white arrow of FIG. 1) of the side exhaust passage 13 in the manifold 18. In such a case, the gas exhaust stream generated in the manifold 18 by discharging the gas in the chamber 11 through the rough exhaust line 15 and/or the main exhaust line 16 can accurately be matched to the free-fall path of the particles, thereby making possible an accurate detection of the sizes and the number of particles in the chamber 11.

The following is a description of a plasma processing chamber in accordance with a second preferred embodiment of the present invention.

This embodiment has essentially the same configuration and operation as those of the first embodiment, except that the particle counter and the gas exhaust ports of the rough exhaust line and the main exhaust line in the manifold are disposed at different locations compared to those of the first embodiment. It is therefore noted that only the differences will be described hereinafter.

In the plasma processing chamber 10, the particle counter 45 is disposed at the side exhaust passage 13. Meanwhile, the plasma in the processing space S may emit stray light depending on plasma processing conditions. Since the side exhaust passage 13 is located close to the processing space S, the detector 50 of the particle counter 45 disposed at the side exhaust passage 13 may receive not only the light reflected from the particles passing through the laser beam 46, but also the stray light generated from the plasma in the processing space S. Consequently, depending on the plasma processing conditions, the particle counter 45 may not be able to precisely detect the sizes and the number of particles. Moreover, the components of the particle counter 45 could be sputtered by ions and/or radicals pulled into the side exhaust passage 13, thereby deteriorating the particle counter 45. To that end, in the plasma processing chamber in accordance with this embodiment, the particle counter is disposed at a manifold 18.

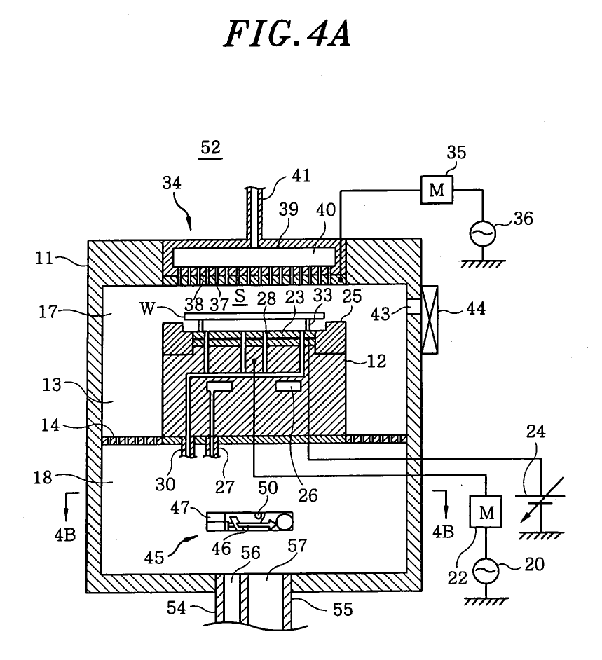

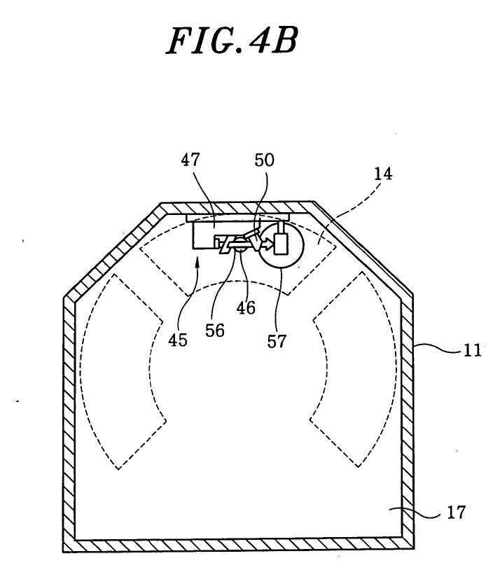

FIG. 4A provides a schematic cross sectional view of the plasma processing chamber in accordance with this embodiment, and FIG. 4B presents a schematic cross sectional view taken along the line 4B-4B of FIG. 4A.

Referring to FIGS. 4A and 4B, a plasma processing chamber 52 is provided with a particle counter 45 disposed in the manifold 18. Further, the manifold 18 is connected with a rough exhaust line 54 (first exhaust passage) and a main exhaust line 55 (second exhaust passage). The rough exhaust line 54 is connected with a DP (not shown), and the main exhaust line 55 is connected with a TMP (not shown). The rough exhaust line 54 depressurizes an inside of the chamber 11 from the atmospheric pressure to a low vacuum level, and the main exhaust line 55 depressurizes the inside of a chamber 11 by cooperating with the rough exhaust line 54 from the atmospheric pressure to a high vacuum level having a pressure lower than the low vacuum level.

The rough exhaust line 54 and the main exhaust line 55 have a rough exhaust port 56 and a main exhaust port 55 opened toward an inside of the manifold 18, respectively. The rough exhaust port 56 and the main exhaust port 57 are adjacently arranged at the bottom surface of the manifold 18 and opened toward the baffle plate 14 (see FIG. 4B). As shown in FIG. 4A, the side exhaust passage 13 is positioned above the baffle plate 14, so that the rough exhaust line 54 and the main exhaust line 55 are opened toward an extended path of the side exhaust passage 13 in the manifold 18. Since the extended path of the side exhaust passage 13 coincides with a free-fall path of the particles, a gas exhaust stream generated in the manifold 18 by discharging the gas from the chamber 11 through the rough exhaust line 54 or the main exhaust line 55 also coincide with the free-fall path of the particles. That is, a moving path of the particles transferred along the gas exhaust stream toward the rough exhaust line .54 and the main exhaust line 55 coincide with the free-fall path of the particles. Accordingly, the particles are constantly introduced into the main exhaust line 57 while the inside of the chamber 11 is being depressurized from the atmospheric pressure to the high vacuum level in which the particles are likely to fall freely.

Further, the particle counter 45 is positioned above the rough exhaust port 56 and the main exhaust port 57 such that a laser generating part 47 emits the laser beam 46 along a direction in which the rough exhaust line 56 and the main exhaust port 57 (see FIG. 4B) are arranged. In other words, the particle counter 45 is provided on the moving path of the particles carried by the gas discharged from the chamber 11 through the rough exhaust line 54 or the main exhaust line 55 and also on the free-fall path of the particles in the manifold 18.

In accordance with the plasma processing chamber 52, the rough exhaust line 54 and the main exhaust line 55 have the rough exhaust port 56 and the main exhaust port 57 opened toward the inside of the chamber 11, respectively. The rough exhaust port 56 and the main exhaust port 57 are adjacently arranged and opened toward the baffle plate 14, i.e. toward the extended path of the side exhaust line 55 in the manifold 18. Therefore, the moving path of the particles transferred along the gas exhaust stream toward the rough exhaust line 54 and the main exhaust line 55 coincides with the free-fall path of the particles. Moreover, as described above, when the pressure in the chamber 11 is comparatively low, the particles fall freely due to gravity. On the other hand, when the pressure in the chamber 11 is comparatively high, the particles move along the gas exhaust stream generated by discharging the gas from the chamber 11. Thus, regardless of the pressure in the chamber 11, the particles move along the same path in the manifold 18. As a result, the particle counter 45 can detect the sizes and the number of particles in the chamber 11 regardless of the pressure therein.

The plasma processing chamber 52 is provided with the particle counter 45 disposed in the manifold 18. The stray light emitted from the plasma in the processing space S is blocked by the baffle plate 14 and thus fails to reach the manifold 18. Moreover, the baffle plate 14 prevents ions and/or radicals from leaking into the manifold 18. Accordingly, it is possible to prevent the detector 50 of the particle counter 45 from receiving the stray light emitted from the plasma in the processing space S and also possible to prevent the components of the particle counter 45 from being sputtered by the ions and/or radicals.

In the plasma processing chamber 52, the laser generating part 47 emits the laser beam for testing along the arrangement direction of the rough exhaust port 56 and the main exhaust port 57, respectively. Further, the particles are constantly introduced into the rough exhaust port 56 and the main exhaust port 57 while the inside of the chamber 11 is being depressurized from the atmospheric pressure to the high vacuum level in which the particles are likely to fall freely. Accordingly, the particle counter 45 can accurately detect a state of particles in the chamber 11 regardless of the pressure therein.

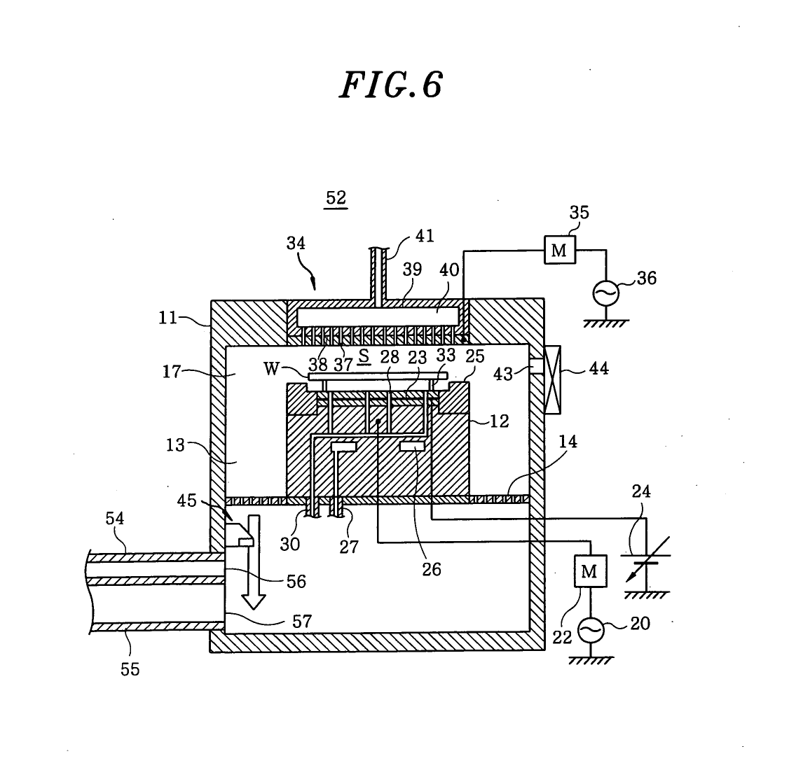

Although the rough exhaust port 56 and the main exhaust port 57 are opened toward the baffle plate 14 at the bottom surface of the manifold 18 in the plasma processing chamber 52, neither the rough exhaust port 56 nor the main exhaust port 57 needs to be opened toward the baffle plate 14. As depicted in FIG. 6, both may be opened only toward the extended path of the side exhaust passage 13 (indicated by a white arrow of FIG. 6) in the manifold 18. In this case, the particle counter 45 is positioned such that the laser generating part 47 emits the laser beam 46 toward the extended path of the side exhaust passage 13.

Hereinafter, a plasma processing chamber in accordance with a third preferred embodiment of the present invention will be explained.

This embodiment essentially has the same configuration and operation as those of the first embodiment, except that the particle counter and the exhaust ports of the rough exhaust line and the main exhaust line in the manifold are disposed at different positions from those in the first embodiment. Therefore, only the difference will be described hereinafter.

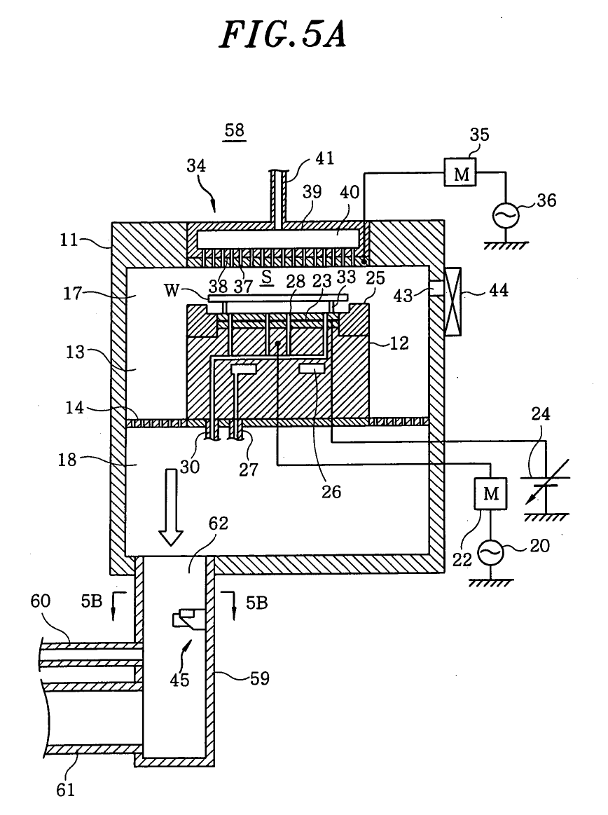

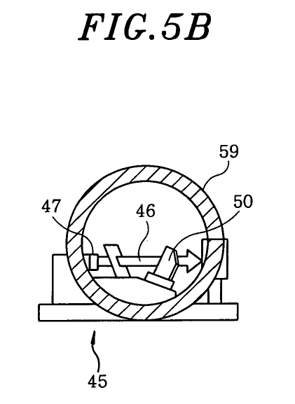

FIG. 5A represents a schematic cross sectional view of the plasma processing chamber in accordance with the third preferred embodiment of the present invention, and FIG. 5B offers a schematic cross sectional view taken along the line II-II of FIG. 5A.

Referring to FIG. 5A, a collective exhaust line 59 (third exhaust passage) for discharging gas from a chamber 11 is connected with a manifold 18 of a plasma processing chamber 58. The collective exhaust line 59 is also connected with a rough exhaust line 60 (first exhaust passage) and a main exhaust line 61 (second exhaust passage). Therefore, the rough exhaust line 60 and the main exhaust line 61 communicate with an inside of the chamber 11 (manifold 18) via the collective exhaust line 59. Further, the rough exhaust line 60 is connected with a DP (not shown), and the main exhaust line 61 is connected with a TMP (not shown). Moreover, the rough exhaust line 60 depressurizes the inside of the chamber 11 by cooperating with the rough exhaust line 60 from the atmospheric pressure to a low vacuum level, and the main exhaust line 61 depressurizes the inside of the chamber 11 from the atmospheric pressure to a high vacuum level having a lower pressure than that of the low vacuum level.

The collective exhaust line 59 has a collective exhaust port 62 opened toward the inside of the manifold 18. To be specific, the collective exhaust port 62 is opened at the bottom surface of the manifold 18 toward the baffle plate 14. As illustrated in FIG. 5A, since the side exhaust passage 13 is positioned above the baffle plate 14, the collective exhaust port 62 is opened toward the extended path (indicated by a white arrow of FIG. 5A) of the side exhaust passage 13 in the manifold 18. Accordingly, the gas exhaust stream generated by discharging the gas from the chamber 11 through the collective exhaust line 59 coincides with the free-fall path of the particles. In other words, a moving path of the particles moving along the gas exhaust stream toward the collective exhaust port 62 coincides with to the free-fall path of the particles. As a result, the particles are constantly introduced into the collective exhaust line 59 while the inside of the chamber 11 is being depressurized from the atmospheric pressure to the high vacuum level in which the particles are likely to fall freely.

In the plasma processing chamber 58, the particle counter 45 is disposed at the collective exhaust line 59 such that the laser generating part 47 emits the laser beam 46 toward a flow path of the collective exhaust line 59 (see FIG. 5B). Specifically, the particle counter 45 is provided more towards the manifold 18 than both the rough exhaust line 60 and the main exhaust line 61 on the collective exhaust line 59. The particle counter 45 detects the sizes and the number of particles flowing in the flow path of the collective exhaust line 59.

According to the plasma processing chamber 58, the collective exhaust line 59 for communicating the rough exhaust line 60 and the main exhaust line 61 with the inside of the chamber 11 has the collective exhaust port 62 opened inside the chamber 11. Specifically, the collective exhaust port 62 is opened toward the baffle plate 14, i.e., toward the extended path of the side exhaust passage 13 in the manifold 18. The path in which the particles move toward the collective exhaust port 62 coincides with the free-fall path of the particles. As described above, in case the pressure in the chamber 11 is comparatively low, the particles fall freely due to gravity, whereas when the pressure in the chamber 11 is comparatively high, the particles move along the exhaust stream of gas discharged from the chamber 11. Consequently, regardless of the pressure in the chamber 11, the particles move along the same path in the manifold 18, and therefore, the particle counter 45 can detect the sizes and the number of particles in the chamber 11 regardless of the pressure therein.

In the plasma processing chamber 58, the particle counter 45 is disposed at the collective exhaust line 59 such that the laser generating part 47 of the particle counter 45 emits the laser beam 46 toward the flow path of the collective exhaust line 59. Moreover, the particles are constantly introduced into the collective exhaust line 59 while the inside of the chamber 11 is being depressurized from the atmospheric pressure to the high vacuum level in which the particles are likely to fall freely. Hence, the particle counter 45 can accurately detect the sizes and the number of particles in the chamber 11 regardless of the pressure therein.

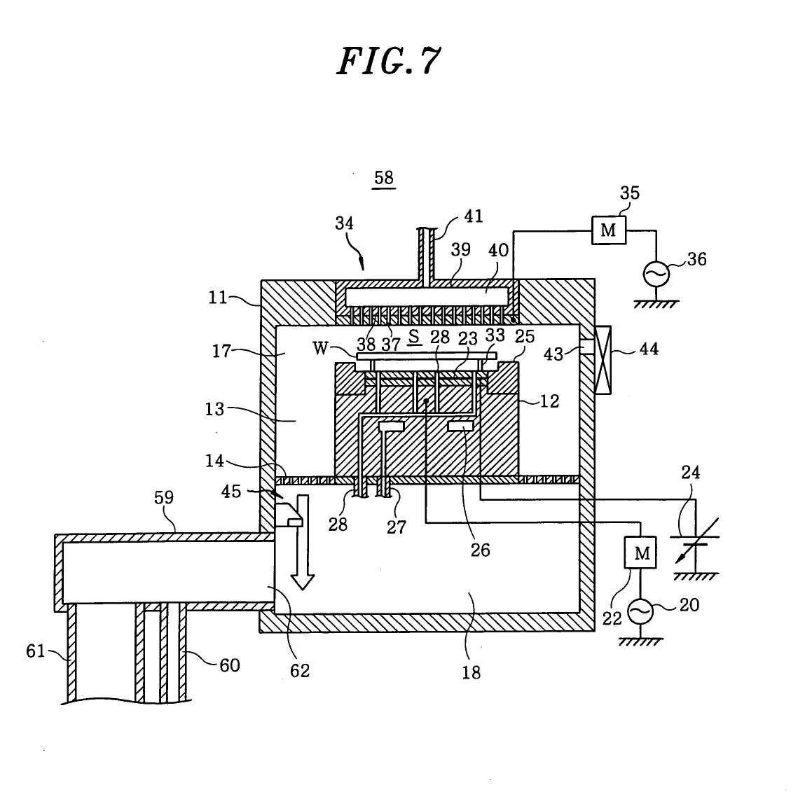

Although the collective exhaust port 62 is opened on the bottom surface of the manifold 18 toward the baffle plate 14 in the plasma processing chamber 58, the collective exhaust part 62 does not need to be opened toward the baffle plate 14. The collective exhaust port 62 may be opened only toward an extended path (indicated by a white arrow of FIG. 7) of the side exhaust passage 13 in the manifold 18, as shown in FIG. 7. In this case, the particle counter 45 is positioned such that the laser generating part 47 emits the laser beam 46 toward the extended path of the side exhaust passage 13.

Furthermore, the plasma processing chamber 58 is provided with the particle counter 45 disposed at the collective exhaust line 59. The stray light emitted from the plasma in the processing space S is blocked by the baffle plate 14 and thus fails to reach the collective exhaust line 59. Moreover, the baffle plate 14 prevents ions and/or radicals from leaking into the manifold 18 and also into the collective exhaust line 59. Accordingly, it is possible to prevent the detector 50 of the particle counter 45 from receiving the stray light emitted from the plasma in the processing space S and also possible to prevent the components of the particle counter 45 from being sputtered by the ions and/or radicals.

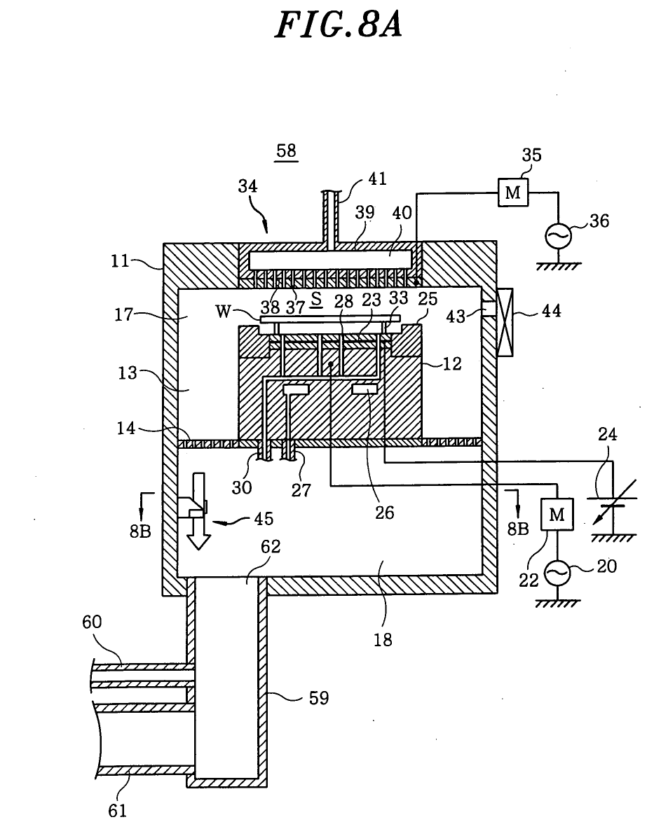

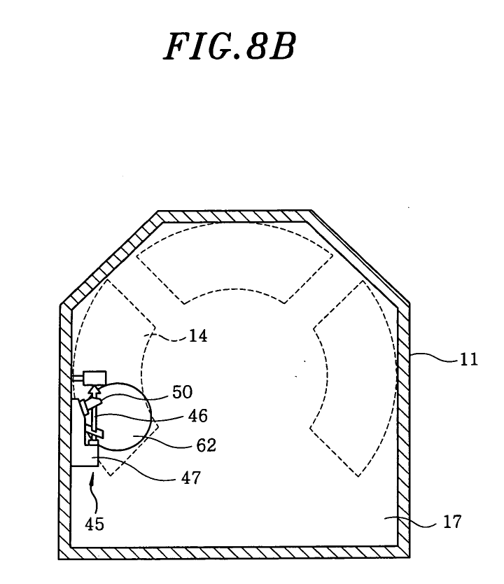

Although the particle counter 45 is provided in the collective exhaust line 59 in the aforementioned plasma processing chamber 58, the particle counter 45 can be disposed at the manifold 18. In such a case, the particle counter 45 is provided such that the laser generating part 47 emits the laser beam 46 toward the extended path (indicated by a white arrow of FIG. 8A) of the side exhaust passage 13. The stray light emitted from the plasma in the processing space S is blocked by the baffle plate 14 and fails to reach the manifold 18. Moreover, the baffle plate 14 prevents ions and/or radicals from leaking into the manifold 18. Also, the particles move along the extended path of the side exhaust passage 13 regardless of the pressure in the chamber 11. Therefore, the particle counter 45 can accurately detect the sizes and the number of particles in the chamber 11 regardless of the pressure therein.

The aforementioned embodiments employ the particle counter 45 using the laser beam. However, types of the particle counter can vary as long as it is able to detect a size and the number of moving particles without changing an atmosphere inside the chamber 11.

Although the plasma processing chambers of the aforementioned embodiments have been applied to an etching processing apparatus, the plasma processing apparatus capable of employing the plasma processing chambers of the aforementioned embodiments could be subject to more than just the etching processing apparatus. For example, they can also be applied to a CVD processing apparatus or an ashing processing apparatus.

Further, a substrate to be subjected to the etching process in the plasma processing chambers of the aforementioned embodiments can apply more than just to a semiconductor wafer. A number of different substrates for use in an LCDC (liquid crystal display), a FPD (flat panel displays) or the like, a photo mask, a CD substrate, a printed circuit board or the like can also be employed.

While the invention has been shown and described with respect to the preferred embodiments, it will be understood by those skilled in the art that various changes and modification may be made without departing from the scope of the invention as defined in the following claims.

What is claimed is:

1. A plasma processing chamber, comprising:
a vessel for accommodating therein a substrate;
a gas supply unit for supplying a processing gas into the vessel;
an electrode for applying a high frequency power into the vessel;
a gas exhaust unit, connected to the vessel, for discharging gas from the vessel; and
a particle detector for detecting particles floating in the vessel,
wherein the particle detector is positioned on a passage functioning as a free-fall path of the particles and also as a moving path of particles carried by the gas discharged from the vessel through the gas exhaust unit.

2. The plasma processing chamber of claim 1, wherein the gas exhaust unit has a gas exhaust port opened in the vessel toward the free-fall path of the particles.

3. A plasma processing chamber, comprising:
a vessel for accommodating therein a substrate;
a gas supply unit for supplying a processing gas into the vessel;
an electrode for applying a high frequency power into the vessel;
a gas exhaust unit, connected to the vessel, for discharging gas in the vessel; and
a particle detector for detecting particles floating in the vessel,
wherein the gas exhaust unit includes a first exhaust passage for depressurizing an inside of the vessel from the atmospheric pressure to a low vacuum level; and a second exhaust passage for depressurizing the inside of the vessel by cooperating with the first exhaust passage from the atmospheric pressure to a high vacuum level having a lower pressure than the low vacuum level, and
wherein the first and the second exhaust passage have a first and a second exhaust port opened in the vessel toward a free-fall path of the particles, respectively.

4. The plasma processing chamber of claim 3, further comprising a partition plate for partitioning the vessel into a reaction chamber where the substrate is disposed and an exhaust chamber connected to the gas exhaust unit, and
wherein the particle detector is provided in the exhaust chamber and has a laser generating part for emitting a laser beam for testing along a direction in which the first and the second exhaust port are arranged.

5. A plasma processing chamber, comprising:
a vessel for accommodating therein a substrate;
a gas supply unit for supplying a processing gas into the vessel;
an electrode for applying a high frequency power into the vessel;
a gas exhaust unit, connected to the vessel, for discharging gas in the vessel; and
a particle detector for detecting particles floating in the vessel,
wherein the gas exhaust unit includes a first exhaust passage for depressurizing an inside of the vessel from the atmospheric pressure to a low vacuum level; a second exhaust passage for depressurizing the inside of the vessel by cooperating with the first exhaust passage from the atmospheric pressure to a high vacuum level having a lower pressure than the low vacuum level; and a third exhaust passage for communicating the first and the second exhaust passage with the inside of the vessel, and wherein the third exhaust passage has an exhaust port opened in the vessel toward a free-fall path of the particles.

6. The plasma processing chamber of claim 5, wherein the particle detector is provided in the third exhaust passage and has a laser generating part for emitting a laser beam for testing toward a flow path of the third exhaust passage.

7. The plasma processing chamber of claim 5, further comprising a partition plate for partitioning the vessel into a reaction chamber where the substrate is disposed and an exhaust chamber connected to the gas exhaust unit, and
wherein the particle detector is provided in the exhaust chamber and has a laser generating part for emitting laser beam for testing toward the free-fall path of the particles.
